(19) United States
(12) Patent Application Publication
(10) Pub. No.: US 2025/0227886 A1
(43) Pub. Date: Jul. 10, 2025

(54) BLOCKING DEVICE AND BLOCKING METHOD THEREOF

(71) Applicant: FIVEGRAND INTERNATIONAL CO., LTD., New Taipei City (TW)

(72) Inventor: TING-JUI WANG, New Taipei City (TW)

(73) Assignee: FIVEGRAND INTERNATIONAL CO., LTD., New Taipei City (TW)

(21) Appl. No.: 18/919,464

(22) Filed: Oct. 18, 2024

(30) Foreign Application Priority Data
Jan. 9, 2024 (TW) 113100942
Apr. 1, 2024 (TW) 113112357

(51) Int. Cl. H05K 7/20

(52) U.S. Cl. CPC H05K 7/2049; H05K 7/20254; H05K 7/20145

(57) ABSTRACT

The present disclosure provides a blocking device and a blocking method thereof, including a blocking structure and an actuating body. The actuating body is movably disposed at the blocking structure, and is assembled with a heat dissipater so as to control a distance between the heat dissipater and a heat generator by the actuating body. Thus, the heat dissipater and the heat generator can be securely coupled by the blocking device of the present disclosure to achieve an effect of effective heat dissipation.

### CROSS-REFERENCE TO RELATED APPLICATION

This non-provisional application claims priority under 35 U.S.C. § 119 (a) on Patent Application No(s). 113100942 filed in Taiwan, R.O.C. on Jan. 9, 2024, and Patent Application No(s). 113112357 filed in Taiwan, R.O.C. on Apr. 1, 2024, the entire contents of which are hereby incorporated by reference.

### BACKGROUND OF THE INVENTION

### 1. Field of the Invention

The present disclosure relates to a blocking device and a blocking method thereof, and in particular to a blocking device capable of securely coupling a heat dissipater and a heat generator to achieve an effect of effective heat dissipation, and a blocking method thereof.

### 2. Description of the Related Art

Heat is usually produced during the operation of a common electronic apparatus. Thus, a gas or fluid cooling apparatus needs to be provided to meet heat dissipation requirements.

However, limited by an internal space of the electronic apparatus, the gas or liquid may not be effectively guided to enter the electronic apparatus to dissipate heat, resulting in degraded heat dissipation efficiency.

Therefore, it is an object of the present disclosure to provide a blocking device and a blocking method thereof, so as to achieve a secure arrangement and effective heat dissipation to thereby effectively improve the drawbacks of the prior art.

### BRIEF SUMMARY OF THE INVENTION

In view of the drawbacks of the prior art above, with extensive and dedicated research and development, the applicant provides a blocking device and a blocking method thereof so as to achieve the objects of a secure arrangement and effective heat dissipation.

To achieve the above and other objects, the present disclosure provides a blocking device including a blocking structure and an actuating body. The actuating body is movably disposed at the blocking structure and is assembled with a heat dissipater, so as to control a distance between the heat dissipater and a heat generator by the actuating body, or to control, by the actuating body and the blocking structure, the heat dissipater to come into contact or not to come into contact with the heat generator.

The present disclosure further provides a blocking method of a blocking device, wherein the actuating body is disposed at the heat dissipater, is for controlling the distance between the heat dissipater and the heat generator by the actuating body and the blocking structure, or is for controlling, by the actuating body and the blocking structure, the heat dissipater to come into contact or not to come into contact with the heat generator.

In one embodiment of the present disclosure, a body is further included. The body is movably disposed at the blocking structure, and the body and the heat dissipater are assembled, or the body and the heat dissipater are formed integrally.

In one embodiment of the present disclosure, the actuating body is twisted into or screwed into a twist-in portion or screw-in portion of the heat dissipater, so as to control the distance between the heat dissipater and the heat generator by the actuating body.

In one embodiment of the present disclosure, the heat dissipater is provided with an engaging connection structure and at least one first elastic element. The engaging connection structure is engagingly connected to an object or a coupling portion, and presses, by elastic force of the first elastic element, the heat dissipater at the heat generator for heat dissipation, or for the heat dissipater to come into contact with or approach the heat generator for heat dissipation, or wherein the heat dissipater is provided with four engaging connection structures and four first elastic elements, and the engaging connection structure is for being engagingly connected to an object or a coupling portion, and for pressing, by elastic force of the first elastic element, the heat dissipater at the heat generator for heat dissipation, or for the heat dissipater to come into contact with or approach the heat generator for heat dissipation, or wherein the heat dissipater is provided with an engaging connection structure, and the engaging connection structure is for being engagingly connected to an object or a coupling portion, for the heat dissipater to be pressed at the heat generator for heat dissipation or for the heat dissipater to come into contact with or approach the heat generator for heat dissipation.

In one embodiment of the present disclosure, the heat dissipater is provided with an engaging connection structure, the blocking structure is provided with at least one open portion, and the open portion is for a tool to enter so as to operate the engaging connection structure or to move out the engaging connection structure from the open portion.

In one embodiment of the present disclosure, the blocking structure or the heat dissipater is provided with at least one alignment portion, which is for alignment of the blocking structure or the heat dissipater.

In one embodiment of the present disclosure, the actuating body or the heat dissipater is a threaded body, an engaging body, a spiral body, a pulling structure, an abutment structure, a screw-in body, a screw or a nut, or the actuating body or a twist-in portion of the heat dissipater is a threaded body, an engaging body, a spiral body, a pulling structure, an abutment structure, a screw-in body, a screw or a nut.

In one embodiment of the present disclosure, the heat dissipater is provided with a passage for circulating a fluid, which is a liquid or a gas for dissipating heat of the heat generator.

In one embodiment of the present disclosure, the actuating body is provided with a blocking portion, which is for limiting a rotation height of the actuating body.

In one embodiment of the present disclosure, the actuating body is provided with a limiting portion, which is for limiting the blocking structure.

In one embodiment of the present disclosure, the actuating body is provided with an operating portion, and a force can be applied to the operating portion to operate the actuating body.

In one embodiment of the present disclosure, the actuating body is provided with an operating portion, the operating portion and the actuating body are bolted and assembled by a bolt, and a force can be applied to the operating portion to operate the actuating body.

In one embodiment of the present disclosure, the actuating body is located at a high abutment position or at a low abutment position during an operation so as to move the blocking structure.

In one embodiment of the present disclosure, the actuating body is a threaded structure, a spiral structure, a pulling structure or an abutment structure.

In one embodiment of the present disclosure, the heat generator is an integrated circuit (IC), a graphics processing unit (GPU), a central processing unit (CPU), a memory or an electronic member.

In one embodiment of the present disclosure, a second elastic element is further included. Two ends of the second elastic element respectively abut against the actuating body and the heat dissipater, or two ends of the second elastic element respectively abut against the blocking structure and the heat dissipater.

In one embodiment of the present disclosure, the actuating body is provided with an operating portion. The operating portion has a guide surface, which guides the actuating body to enter an entry portion for the actuating body to be located and move at a high abutment position or at a low abutment position.

In one embodiment of the present disclosure, the actuating body is provided with an operating portion. The operating portion laterally blocks the actuating body for the actuating body to be located and move at a high abutment position or at a low abutment position.

In one embodiment of the present disclosure, the actuating body abuts against an object by the blocking structure during an operation and pulls the heat dissipater upward, so that a distance is present between the heat dissipater and the heat generator.

In one embodiment of the present disclosure, the actuating body and the heat dissipater are locked, twist connected, screwed, engaged, bolted, adhered, expansion connected, riveted, welded or formed integrally.

In one embodiment of the present disclosure, the blocking structure has a restricting portion. The restricting portion restricts a position of the actuating body, or the restricting portion restricts a position of an operating portion of the actuating body, or the restricting portion restricts the actuating body to control or limit a distance between or positions of the heat dissipater and the heat generator.

In one embodiment of the present disclosure, the actuating body presses the blocking structure downward to abut the blocking structure at an object, and the actuating body is further pressed downward to pull the heat dissipater upward, so that a distance is present between the heat dissipater and the heat generator or a distance between the heat dissipater and the heat generator is increased.

In one embodiment of the present disclosure, the actuating body is provided with an operating portion. The operating portion is operated by a tool, or the operating portion is operated to assemble the actuating body with the heat dissipater or the blocking structure, or an anti-loosening object is provided between the actuating body and the heat dissipater.

In one embodiment of the present disclosure, the actuating body is provided with a stop portion. The stop portion limits and assembles the actuating body and the blocking structure, and is provided with an elastic element. Two ends of the elastic element respectively abut against the actuating body and the blocking structure, wherein the stop portion is a sheet, a washer or a sleeve film, or the stop portion and the actuating body are formed integrally.

In one embodiment of the present disclosure, the blocking device is assembled with a coupling portion, or the coupling portion is for being arranged at an object, or the coupling portion is an object arranged with the heat generator, or the coupling portion is the object, or the object is a printed circuit board, or the coupling portion is a metal body, or the coupling portion or the object is for surrounding the heat generator, a chip or a chip heat generator, or the coupling portion is an object defining a coupling height, or the coupling portion is a heat dissipater, or the coupling portion is an engaging body, an engaged body, an assembly portion or a conductive body.

In one embodiment of the present disclosure, the heat dissipater is provided with an engaging connection structure, or the engaging connection structure is a threaded body, a column body, an outer engaging body, an inner engaging body, an elastic engaging body or an inner threaded body, or wherein the heat generator is a chip, an IC, a GPU, a CPU, a memory, a heat dissipater, a non-metal body, a metal body, a conductive body or a battery, or the heat generator is disposed at an object, and the object is a printed circuit board, a chip, a conductive body, silicon wafer, a heat dissipater, a non-metal body or a metal body, or the heat dissipater is provided with an engaging connection structure, wherein a first elastic element is included, the first elastic element is a spring, an elastic piece, an elastic column, or an elastic sheet, or the heat dissipater is a fin body, a block body or a stacked body, or the heat generator and the heat dissipater are placed in a server, a memory, a computer or a data center, or the heat dissipater is a system having liquid circulation heat transfer.

In one embodiment of the present disclosure, the actuating body or the heat dissipater includes a threaded structure, a screw structure, a rotation structure, an inclined structure or an abutment structure; or a pitch of the threaded structure is configured to decide a number of turn or an angle of rotation of the threaded structure when the heat dissipater contacts with the heat generator; or a pitch of the screw structure is configured to decide a number of turn or an angle of rotation of the screw structure when the heat dissipater contacts with the heat generator; or a pitch of the rotation structure is configured to decide a number of turn or an angle of rotation of the rotation structure when the heat dissipater contacts with the heat generator; or the threaded structure, the screw structure, the rotation structure, the inclined structure or the abutment structure is an external thread structure, an internal thread structure, an up and down moving rotation structure or a leverage structure.

The present disclosure further provides a blocking method of a blocking device. The heat dissipater is provided with an engaging connection structure and one first elastic element. The engaging connection structure is for being engagingly connected to an object or a coupling portion, and for pressing, by elastic force of the first elastic element, the heat dissipater at the heat generator for heat dissipation, or for the heat dissipater to come into contact with or approach the heat generator for heat dissipation, or wherein the heat dissipater is provided with four engaging connection structures and four first elastic elements, and the engaging connection structure is for being engagingly connected to an object or a coupling portion, and for pressing, by elastic force of the first elastic element, the heat dissipater at the heat generator for heat dissipation, or for the heat dissipater to come into contact with or approach the heat generator for heat dissipation, or wherein the heat dissipater is provided with an engaging connection structure, and the engaging connection structure is for being engagingly connected to an object or a coupling portion, for the heat dissipater to be pressed at the heat generator for heat dissipation or for the heat dissipater to come into contact with or approach the heat generator for heat dissipation, or wherein the actuating body abuts against an object by the blocking structure during an operation to pull the heat dissipater upward, so that a distance is present between the heat dissipater and the heat generator.

The present disclosure further provides a blocking method of a blocking device including a blocking structure and an actuating body. The actuating body is disposed at the blocking structure and is for being disposed at a heat dissipater, so as to control a distance between the heat dissipater and a heat generator by the actuating body, or to control, by the actuating body and the blocking structure, the heat dissipater to come into contact or not to come into contact with the heat generator.

In one embodiment of the present disclosure, the actuating body or the heat dissipater includes a threaded structure, a screw structure, a rotation structure, an inclined structure or an abutment structure; or a pitch of the threaded structure is configured to decide a number of turn or an angle of rotation of the threaded structure when the heat dissipater contacts with the heat generator; or a pitch of the screw structure is configured to decide a number of turn or an angle of rotation of the screw structure when the heat dissipater contacts with the heat generator; or a pitch of the rotation structure is configured to decide a number of turn or an angle of rotation of the rotation structure when the heat dissipater contacts with the heat generator; or the threaded structure, the screw structure, the rotation structure, the inclined structure or the abutment structure is an external thread structure, an internal thread structure, an up and down moving rotation structure or a leverage structure.

The present disclosure further provides a blocking method of a blocking device including a blocking structure and an actuating body. The actuating body is disposed at the blocking structure and is for being disposed at a heat dissipater, so as to control a distance between the heat dissipater and a heat generator by the actuating body, or to control, by the actuating body and the blocking structure, the heat dissipater to come into contact or not to come into contact with the heat generator. The heat dissipater is provided with an engaging connection structure and one first elastic element, or the engaging connection structure is for being engagingly connected to an object or a coupling portion, or is for pressing, by elastic force of the first elastic element, the heat dissipater at the heat generator for heat dissipation, or for the heat dissipater to come into contact with or approach the heat generator for heat dissipation, or wherein the heat dissipater is provided with four engaging connection structures and four first elastic elements, or the engaging connection structure is for being engagingly connected to an object or a coupling portion, or is for pressing, by elastic force of the first elastic element, the heat dissipater at the heat generator for heat dissipation, or is for the heat dissipater to come into contact with or approach the heat generator for heat dissipation, or wherein the heat dissipater is provided with an engaging connection structure, or the engaging connection structure is for being engagingly connected to an object or a coupling portion, for the heat dissipater to be pressed at the heat generator for heat dissipation or for the heat dissipater to come into contact with or approach the heat generator for heat dissipation, or wherein the actuating body abuts against an object by the blocking structure during an operation to pull the heat dissipater upward, so that a distance is present between the heat dissipater and the heat generator.

Thus, the blocking device and the blocking method thereof of the present disclosure can securely couple the heat dissipater and the heat generator to achieve an effect of effective heat dissipation.

### BRIEF DESCRIPTION OF THE DRAWINGS

FIG. 1 is a schematic diagram of a first specific embodiment of the present disclosure.

FIG. 2 is a schematic diagram of the first specific embodiment of the present disclosure.

FIG. 3 is a schematic diagram of a second specific embodiment of the present disclosure.

FIG. 4 is a schematic diagram of a third specific embodiment of the present disclosure.

FIG. 5 is a schematic diagram of a fourth specific embodiment of the present disclosure.

FIG. 6 is a schematic diagram of a fifth specific embodiment of the present disclosure.

FIG. 7 is a schematic diagram of a sixth specific embodiment of the present disclosure.

FIG. 8 is a schematic diagram of a seventh specific embodiment of the present disclosure

FIG. 9 is a schematic diagram of an eighth specific embodiment of the present disclosure.

FIG. 10 is a schematic diagram of the eighth specific embodiment of the present disclosure.

FIG. 11 is a schematic diagram of a ninth specific embodiment of the present disclosure.

FIG. 12 is a schematic diagram of the ninth specific embodiment of the present disclosure.

FIG. 13 is a schematic diagram of a tenth specific embodiment of the present disclosure.

FIG. 14 is a schematic diagram of the tenth specific embodiment of the present disclosure.

FIG. 15 is a schematic diagram of an eleventh specific embodiment of the present disclosure.

FIG. 16 is a schematic diagram of a twelfth specific embodiment of the present disclosure.

FIG. 17 is a schematic diagram of the twelfth specific embodiment of the present disclosure.

FIG. 18 is a schematic diagram of different forms of an engaging connection structure of the present disclosure.

FIG. 19 is a schematic diagram of a thirteenth specific embodiment of the present disclosure.

FIG. 20 is a schematic diagram of a fourteenth specific embodiment of the present disclosure.

### DETAILED DESCRIPTION OF THE INVENTION

To facilitate understanding of the object, characteristics and effects of the present disclosure, embodiments together with the attached drawings for the detailed description of the present disclosure are provided below.

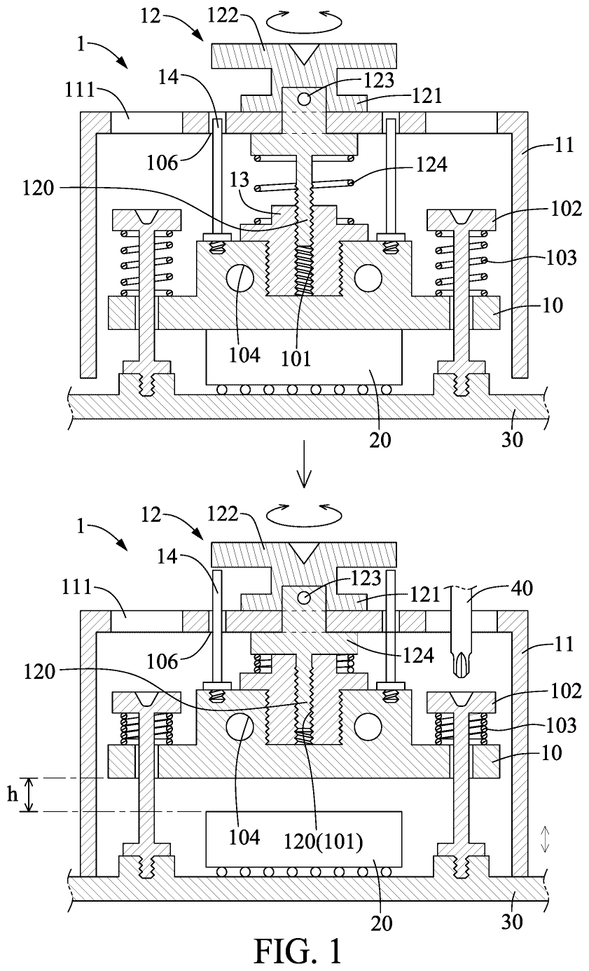

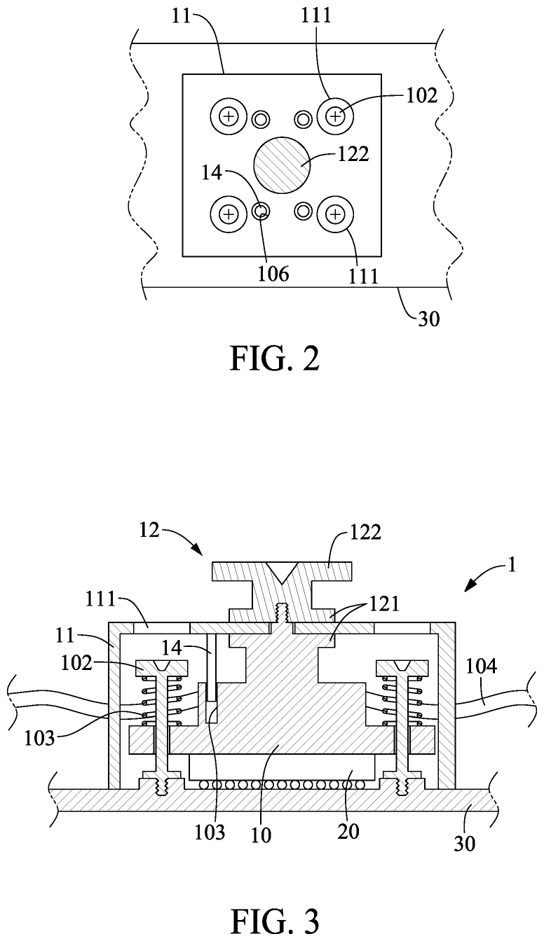

Referring to FIG. 1 to FIG. 3, as shown in the drawings, the present disclosure provides a blocking device 1 and a blocking method thereof. The blocking device 1 at least includes a blocking structure 11 and an actuating body 12.

The actuating body 12 is movably disposed at the blocking structure 11 and is assembled with a heat dissipater 10, so as to control a distance h (for example, a predetermined distance, a decreased distance or no distance) between the heat dissipater 10 and a heat generator 20 by the actuating body 12. Thus, the heat dissipater 10 and the heat generator 20 can be securely coupled to achieve an effect of effective heat dissipation.

Moreover, the heat dissipater 10 can also be controlled, by the actuating body 12 and the blocking structure 11, whether to come into contact or not to come into contact with the heat generator 20, hence achieving an effect of effective heat dissipation.

On the basis of the embodiment above, in the blocking method of the blocking device of the present disclosure, the actuating body 12 can be operated and assembled with the heat dissipater 10, so as to move the actuating body 12 to control the distance h between the heat dissipater 10 and the heat generator 20. For example, by moving the actuating body 12, the heat dissipater 10 and the heat generator 20 are controlled such there is no distance h between the two and the two exhibit a state of attaching to each other, further for the heat dissipater 10 and the heat generator 20 to abut against and be securely coupled with each other. By controlling the distance between the heat dissipater 10 and the heat generator 20 by the actuating body 12 and the blocking structure 11, the heat dissipater 10 is controlled, by the actuating body 12 and the blocking structure 11, to come into contact or not to come into contact with the heat generator 20, hence achieving an effect of effective heat dissipation.

In addition to the embodiment above, in one embodiment of the present disclosure, a difference from the embodiments above is that, the heat generator 20 is an integrated circuit (IC), a graphics processing unit (GPU), a central processing unit (CPU), a memory, a heat dissipater, a non-metal body, a metal body or an electronic member. Thus, the present disclosure is able to better meet actual application requirements.

In addition to the embodiment above, in one embodiment of the present disclosure, a difference from the embodiments above is that, a body 13 is further included. The body 13 is movably disposed at the blocking structure 11 and is assembled with the heat dissipater 10, the actuating body 12 is movably disposed at the body 13 and can be a threaded structure (a twist-in structure, a pulling structure or an abutment structure), and the heat dissipater 10 is provided with a twist-in portion 101 (or a screw-in portion). Thus, the actuating body 12 can be twisted into or screwed into the twist-in portion 101 (or the screw-in portion) of the heat dissipater 10 by coordinating with the body 13, hence controlling the heat dissipater 10 and the heat generator 20 by lock connection of the actuating body 12 such there is no distance h between the two and the two are in a state of attaching to each other, further for the heat dissipater 10 and the heat generator 20 to abut against and be securely coupled with each other to achieve an effect of effective heat dissipation.

In addition to the embodiment above, in one embodiment of the present disclosure, a difference from the embodiments above is that, the body 13 can be formed integrally with the heat dissipater 10 according to requirements. Thus, the present disclosure is able to better meet actual application requirements.

In addition to the embodiment above, in one embodiment of the present disclosure, a difference from the embodiments above is that, the actuating body 12 or the heat dissipater 10 can be a threaded body, an engaging body, a spiral body, a pulling structure, an abutment structure, a screw-in body, a screw or a nut. Thus, the present disclosure is able to better meet actual application requirements.

In addition to the embodiment above, in one embodiment of the present disclosure, a difference from the embodiments above is that, the actuating body 12 or the twist-in portion 101 can be a threaded body, an engaging body, a spiral body, a pulling structure, an abutment structure, a screw-in body, a screw or a nut. Thus, the present disclosure is able to better meet actual application requirements.

In addition to the embodiment above, in one embodiment of the present disclosure, a difference from the embodiments above is that, the heat dissipater 10 is provided with an engaging connection structure 102 and at least one first elastic element 103. The engaging connection structure 102 is engagingly connected to an object 30 (or a coupling portion), and presses, by elastic force of the first elastic element 103, the heat dissipater 10 at the heat generator 20 for heat dissipation (or for the heat dissipater 10 to come into contact with or approach the heat generator 20 for heat dissipation). Meanwhile, the actuating body 12 is twisted into or screwed into the twist-in portion 101 (or the screw-in portion) of the heat dissipater 10, hence controlling the heat dissipater 10 and the heat generator 20 by lock connection of the actuating body 12 such there is no distance h between the two and the two are in a state of attaching to each other, further for the heat dissipater 10 and the heat generator 20 to abut against and be securely coupled with each other to achieve an effect of effective heat dissipation.

In addition to the embodiment above, in one embodiment of the present disclosure, a difference from the embodiments above is that, the heat dissipater 10 is provided with four engaging connection structures 102 and four first elastic elements 103. The engaging connection structure 102 is for being engagingly connected to the object 30 (or a coupling portion), and for pressing, by elastic force of the first elastic element 103, the heat dissipater 10 at the heat generator 20 for heat dissipation (or for the heat dissipater 10 to come into contact with or approach the heat generator 20 for heat dissipation).

In addition to the embodiment above, in one embodiment of the present disclosure, a difference from the embodiments above is that, the blocking structure 11 is provided with at least one open portion 111, and the open portion 111 is for a tool 40 to enter so as to operate the engaging connection structure 102 or to move out the engaging connection structure 102 from the open portion 111. Thus, ease of operation and use is achieved.

In addition to the embodiment above, in one embodiment of the present disclosure, a difference from the embodiments above is that, at least one alignment portion 14, 106 is provided between the blocking structure 11 and the heat dissipater 10, and the alignment portion 14, 106 is for alignment of the blocking structure 11 or the heat dissipater 10. Thus, when the actuating body 12 is twisted into or screwed into the twist-in portion 101 of the heat dissipater 10, the heat dissipater 10 and the heat generator 20 can abut against and be securely coupled with each other to achieve an effect of effective heat dissipation.

In addition to the embodiment above, in one embodiment of the present disclosure, a difference from the embodiments above is that, the actuating body 12 has a twist connection portion 120 for connecting with the twist-in portion 101. Each of the twist connection portion 120 and the twist-in portion 101 of the heat dissipater 10 can be a threaded body, an engaging body, a screw-in body, a spiral body, a screw or a nut. Thus, the lock connection of the actuating body 12 and the twist-in portion 101 can better meet actual application requirements.

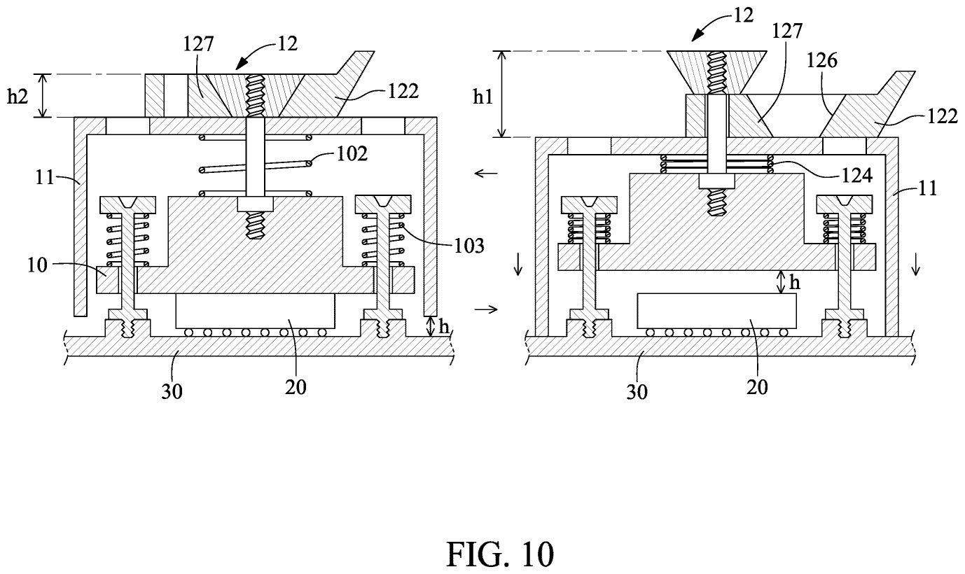

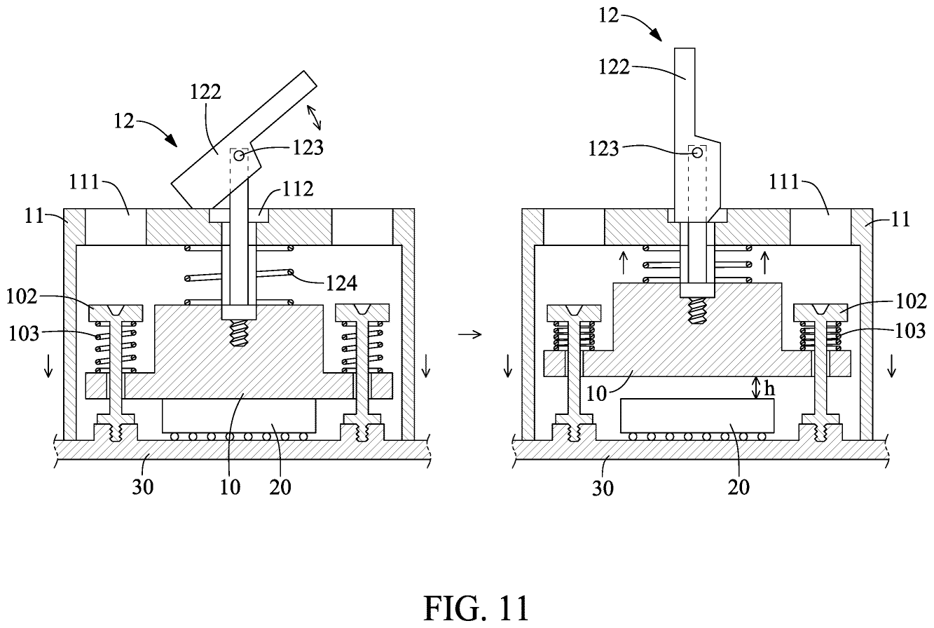

In addition to the embodiment above, in one embodiment of the present disclosure, a difference from the embodiments above is that, the actuating body 12 and the heat dissipater 10 include a threaded structure, a screw structure (for example, the twist connection portion 120 of the actuating body 12 and the twist-in portion 101 of the heat dissipater 10), a rotation structure, an inclined structure or an abutment structure (as shown in FIG. 10 and FIG. 11). Wherein, a pitch of the threaded structure is configured to decide a number of turn or an angle of rotation of the threaded structure when the heat dissipater 10 contacts with the heat generator 20; or a pitch of the screw structure is configured to decide a number of turn or an angle of rotation of the screw structure when the heat dissipater 10 contacts with the heat generator 20; or a pitch of the rotation structure is configured to decide a number of turn or an angle of rotation of the rotation structure when the heat dissipater 10 contacts with the heat generator 20. The threaded structure, the screw structure, the rotation structure, the inclined structure or the abutment structure (as shown in FIG. 10 and FIG. 11) can be an external thread structure, an internal thread structure, an up and down moving rotation structure or a leverage structure (as shown in FIG. 10 and FIG. 11).

In addition to the embodiment above, in one embodiment of the present disclosure, a difference from the embodiments above is that, the actuating body 12 is provided with a limiting portion 121 which is for limiting the blocking structure 11, the actuating body 12 is further provided with an operating portion 122, and the operating portion 122 and the actuating body 12 are bolted and assembled by a bolt 123, so as to apply a force to the operating portion 122 to operate the actuating body 12. Thus, a force can be applied to the operating portion 122 to operate the actuating body 12, and drive the blocking structure 11 by the limiting portion 121 when the actuating body 12 moves. When the actuating body 12 is twisted into or screwed into the twist-in portion 101 of the heat dissipater 10, in addition to abutting the blocking structure 11 against the object 30, the heat dissipater 10 and the heat generator 20 are controlled by lock connection of the actuating body 12 such there is no distance h between the two and the two are in a state of attaching to each other, further for the heat dissipater 10 and the heat generator 20 to abut against and be securely coupled with each other to achieve an effect of effective heat dissipation.

In addition to the embodiment above, in one embodiment of the present disclosure, a difference from the embodiments above is that, a second elastic element 124 is further included. Two ends of the second elastic element 124 respectively abut against the actuating body 12 and the heat dissipater 10 (or two ends of the second elastic element 124 can respectively abut against the blocking structure 11 and the heat dissipater 10 according to requirements). Thus, with the coordination of the first elastic element 103 and the second elastic element 124, the engaging connection structure 102 and the actuating body 12 can be elastically pressed at the heat dissipater 10, for the heat dissipater 10 to be securely pressed at the heat generator 20 for heat dissipation.

In addition to the embodiment above, in one embodiment of the present disclosure, a difference from the embodiments above is that, the heat dissipater 10 is provided with a passage 104 for circulating a fluid, which is a liquid or a gas for dissipating heat of the heat generator 20. Thus, once a heat source of the heat generator 20 is absorbed by the heat dissipater 10, the fluid is guided to flow through the heat dissipater 10 by the passage 104 to achieve an effect of effective heat dissipation.

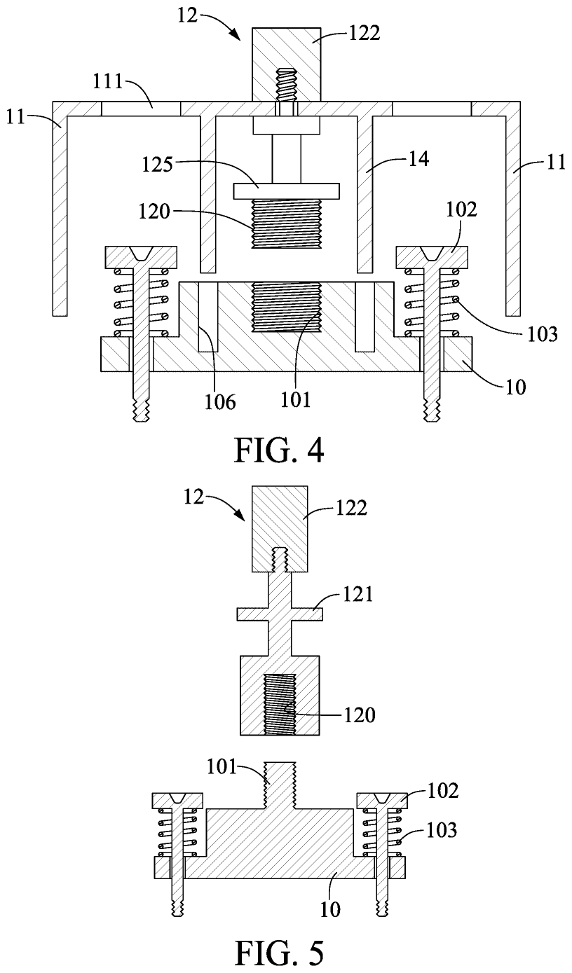

Referring to FIG. 4 and FIG. 5, as shown in the drawings, in addition to the embodiments above, in one embodiment of the present disclosure, a difference from the embodiments above is that, the actuating body 12 is provided with a blocking portion 125, which is for limiting a rotation height of the actuating body 12. By controlling the distance h between the heat dissipater 10 and the heat generator 20 by means of operating the actuating body 12, the heat dissipater 10 and the heat generator 20 are securely coupled to achieve an effect of effective heat dissipation.

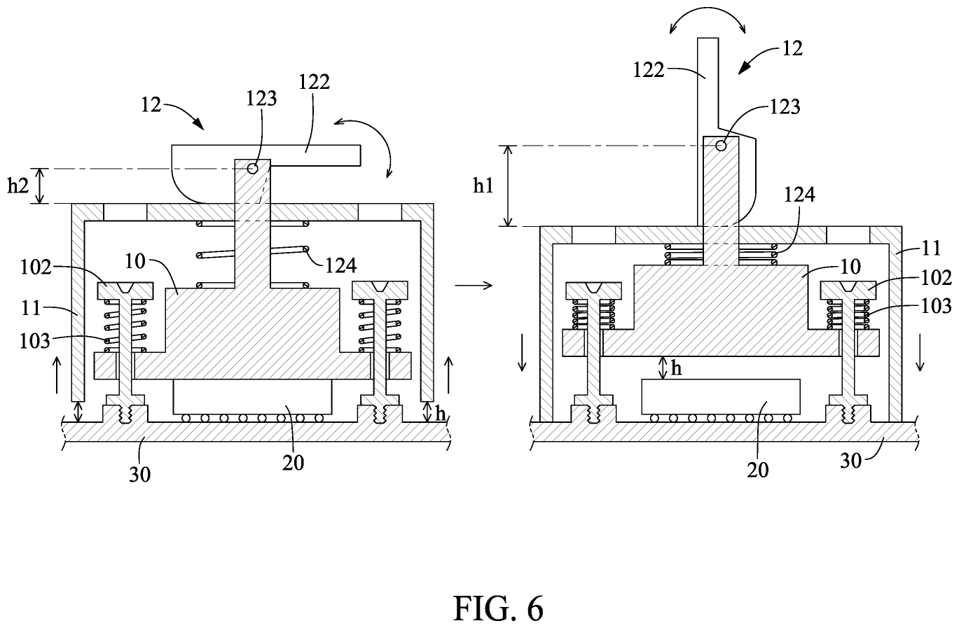

Referring to FIG. 6, as shown in the drawing, in addition to the embodiments above, in one embodiment of the present disclosure, a difference from the embodiments above is that, the operating portion 122 and the actuating body 12 are bolted and assembled by the bolt 123. The actuating body 12 can be operated by applying a force to the operating portion 122, further for the actuating body 12 to be located at a high abutment position h1 or a low abutment position h2 when the actuating body 12 is in operation so as to move the blocking structure 11.

In addition to the embodiment above, in one embodiment of the present disclosure, a difference from the embodiments above is that, the operating portion 122 of the actuating body 12 is a pulling structure, and the actuating body 12 can be an abutment structure.

On the basis of the embodiment above, a force can be applied to the operating portion 122 to move the operating portion 122 from the low abutment position h2 to the high abutment position h1, so as to operate the actuating body 12 to move up and down, and drive the blocking structure 11 by the limiting portion 121 when the actuating body 12 moves. When the actuating body 12 abuts against the heat dissipater 10, in addition to abutting the blocking structure 11 against the object 30, the heat dissipater 10 and the heat generator 20 are controlled by lock connection of the actuating body 12 such there is no distance h between the two and the two are in a state of attaching to each other, further for the heat dissipater 10 and the heat generator 20 to abut against and be securely coupled with each other to achieve an effect of effective heat dissipation.

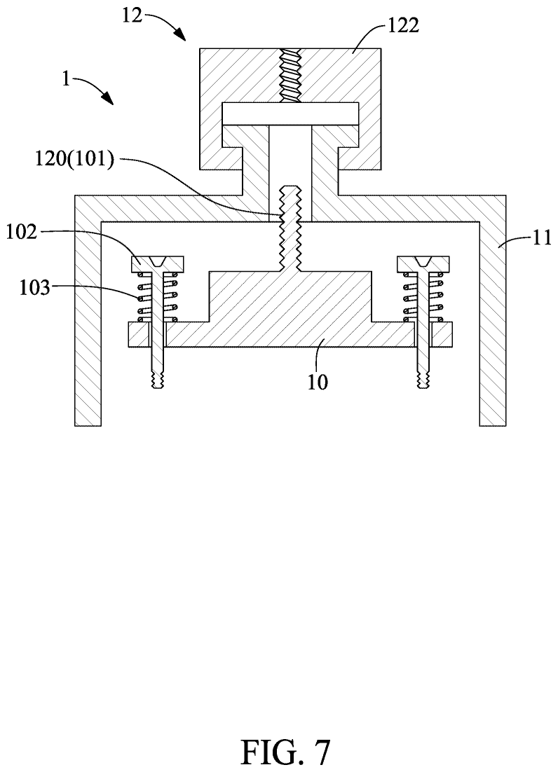

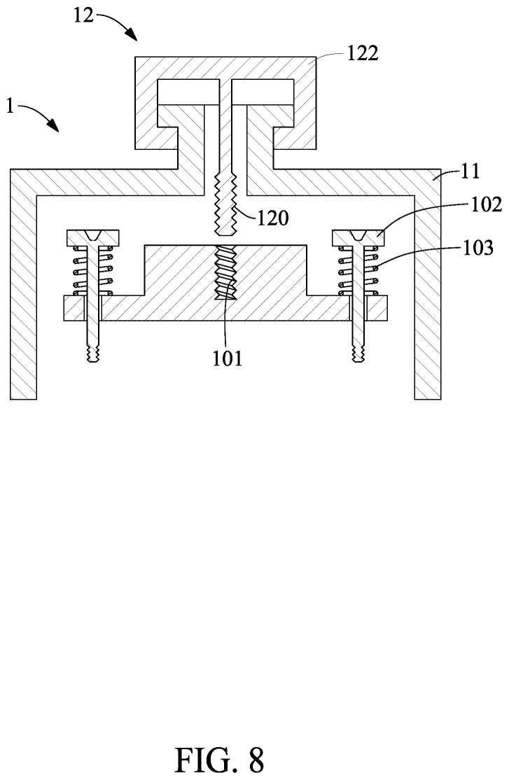

Referring to FIG. 7 and FIG. 8, as shown in the drawings, in addition to the embodiments above, in one embodiment of the present disclosure, a difference from the embodiments above is that, in addition to the above coupling means of the actuating body 12 and the heat dissipater 10, the two can be further locked, twist connected, screwed, engaged, bolted, adhered, expansion connected, riveted, welded or integrally formed as required. Thus, the heat dissipater 10 and the heat generator 20 can also be controlled by the actuating body 12 such there is no distance h between the two and the two are in a state of attaching to each other, further for the heat dissipater 10 and the heat generator 20 to abut against and be securely coupled with each other to achieve an effect of effective heat dissipation.

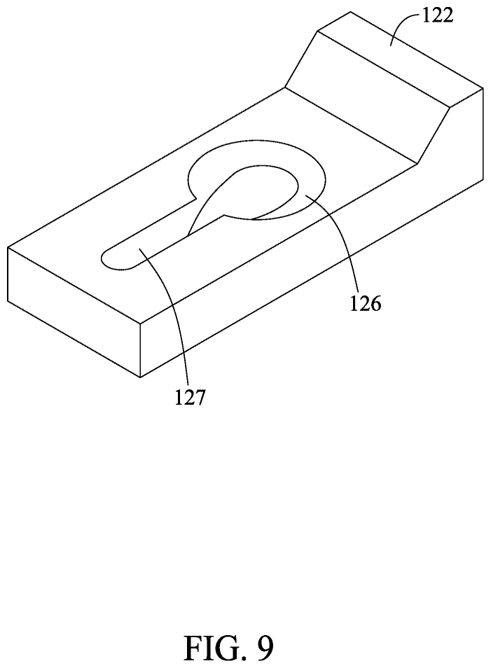

Referring to FIG. 9 and FIG. 10, as shown in the drawings, in addition to the embodiments above, in one embodiment of the present disclosure, a difference from the embodiments above is that, the actuating body 12 is provided with an operating portion 122, and the operating portion 122 has a guide surface 126 which can guide the actuating body 12 to move into an entry portion 127, for the actuating body 12 to be located and move at a high abutment position h1 or a low abutment position h2. For example, the distance h is present between the heat dissipater 10 and the heat generator 20 when the actuating body 12 is located at the high abutment position h1, and there is no distance h between the heat dissipater 10 and the heat generator 20 when the actuating body 12 is located at the low abutment position h2. Thus, the present disclosure is able to better meet actual application requirements.

In addition to the embodiment above, in one embodiment of the present disclosure, a difference from the embodiments above is that, the operating portion 122 laterally blocks the actuating body 12 for the actuating body 12 to move from the high abutment position h1 to the low abutment position h2 or move from the low abutment position h2 to the high abutment position h1. Thus, the present disclosure is able to better meet actual application requirements.

In addition to the embodiment above, in one embodiment of the present disclosure, a difference from the embodiments above is that, the actuating body 12 blocks the object 30 by the blocking structure 11 during an operation and pulls the heat dissipater 10 upward, so that the distance h is present between the heat dissipater 10 and the heat generator 20. Thus, the present disclosure is able to better meet actual application requirements.

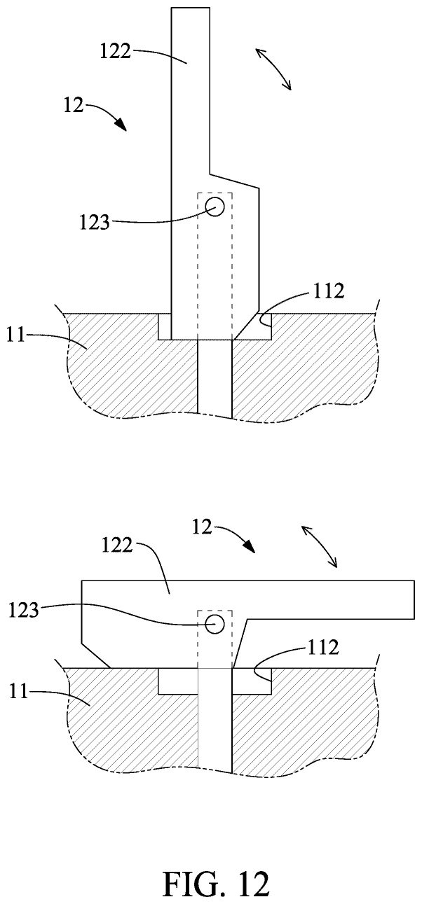

Referring to FIG. 11 and FIG. 12, as shown in the drawings, in addition to the embodiments above, in one embodiment of the present disclosure, a difference from the embodiments above is that, the blocking structure 11 is provided with a restricting portion 112. The restricting portion 112 can restrict an operation position of the actuating body 12, or the restricting portion 112 can restrict an operation position of the operating portion 122, or the restricting portion 112 restricts the actuating body 12 to control (or limit) a distance between or positions of the heat dissipater 10 and the heat generator 20.

On the basis of the embodiment above, the actuating body 12 can press the blocking structure 11 downward to abut the blocking structure 11 against the object 30, and the actuating body 12 is further pressed downward to pull the heat dissipater 10 upward, so that the distance h is present between the heat dissipater 10 and the heat generator 20 or the distance h between the heat dissipater 10 and the heat generator 20 is increased.

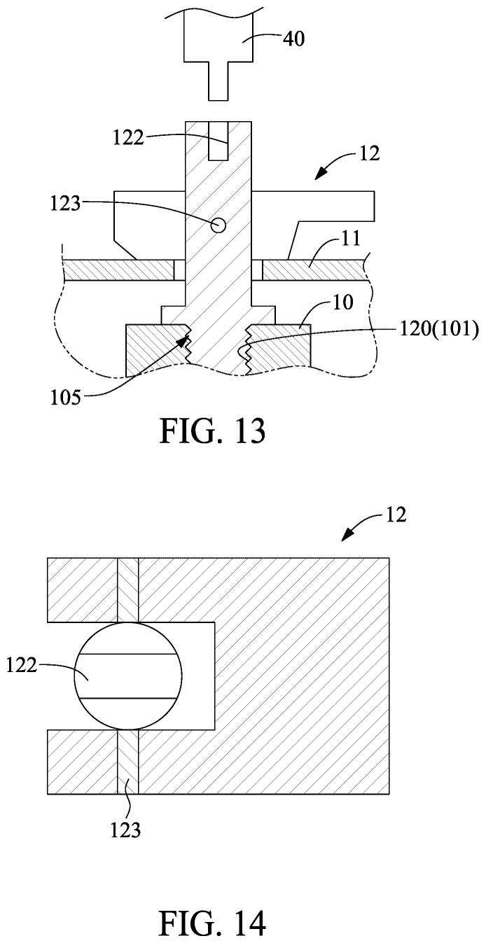

Referring to FIG. 13 and FIG. 14, as shown in the drawings, in addition to the embodiments above, in one embodiment of the present disclosure, a difference from the embodiments above is that, the operating portion 122 is operated by a tool 40 for the operating portion 122 to assemble the actuating body 12 with the heat dissipater 10 and the blocking structure 11. Moreover, an anti-loosening object 105 is provided between the actuating body 12 and the heat dissipater 10. Thus, the present disclosure is able to better meet actual application requirements.

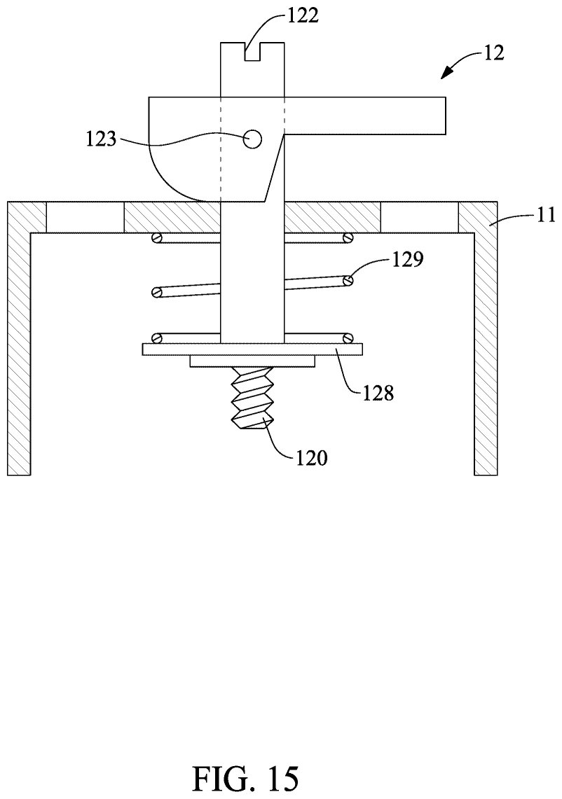

Referring to FIG. 15, as shown in the drawing, in addition to the embodiments above, in one embodiment of the present disclosure, a difference from the embodiments above is that, the actuating body 12 is provided with a stop portion 128. The stop portion 128 limits and assembles the actuating body 12 and the blocking structure 11, and is provided with an elastic element 129. Two ends of the elastic element 129 respectively abut against the stop portion 128 of the actuating body 12 and the blocking structure 11, wherein the stop portion 128 is a sheet, a washer or a sleeve film, or the stop portion 128 and the actuating body 12 are formed integrally. Thus, the present disclosure is able to better meet actual application requirements.

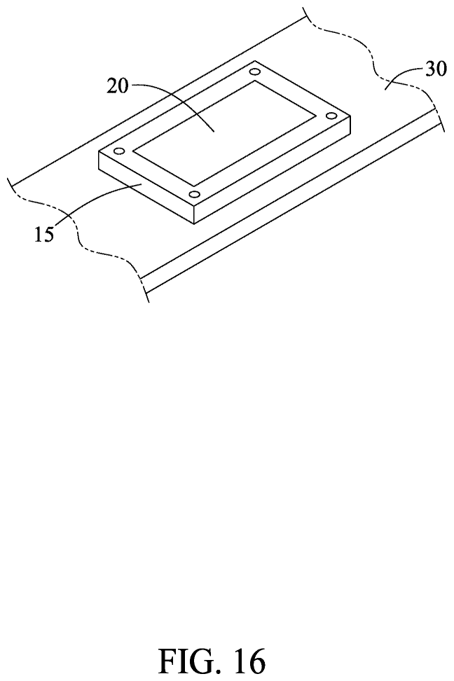

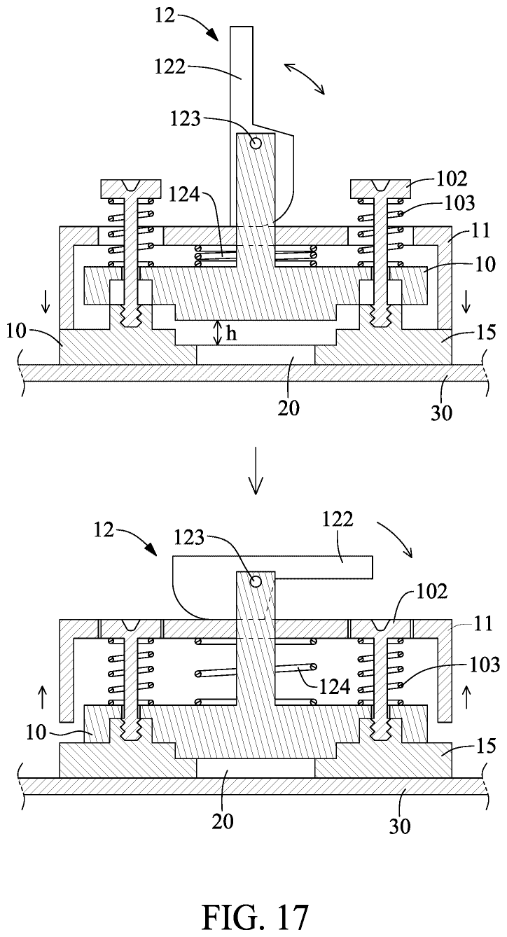

Referring to FIG. 16 and FIG. 17, as shown in the drawings, in addition to the embodiments above, in one embodiment of the present disclosure, a difference from the embodiments above is that, the blocking structure 11 of the blocking device 1 is assembled with a coupling portion 15, the coupling portion 15 is for being assembled and arranged at the object 30 (or the object 30 arranged with the heat generator 20, or the coupling portion 15 is the object 30, or the coupling portion 15 can be a metal body), and the object 30 can be a printed circuit board for the coupling portion 15 (or the object 30) to surround the heat generator 20 (for example, a chip or a chip heat generator), and the coupling portion 15 can be an object defining a coupling height, or the coupling portion 15 can be coupled with the heat dissipater 10, or the coupling portion 15 can be the heat dissipater 10, or the coupling portion 15 can be an engaging body, an engaged body, an assembly portion or a conductive body. Thus, the present disclosure is able to better meet actual application requirements.

In addition to the embodiment above, in one embodiment of the present disclosure, a difference from the embodiments above is that, the engaging connection structure 102 of the heat dissipater 10 is provided with a coupling portion 15 for being engagingly connected to the object 30, for the heat dissipater 10 to be pressed at the heat generator 20 for heat dissipation (or for the heat dissipater 10 to come into contact with or approach the heat generator 20 for heat dissipation). Thus, the present disclosure is able to better meet actual application requirements.

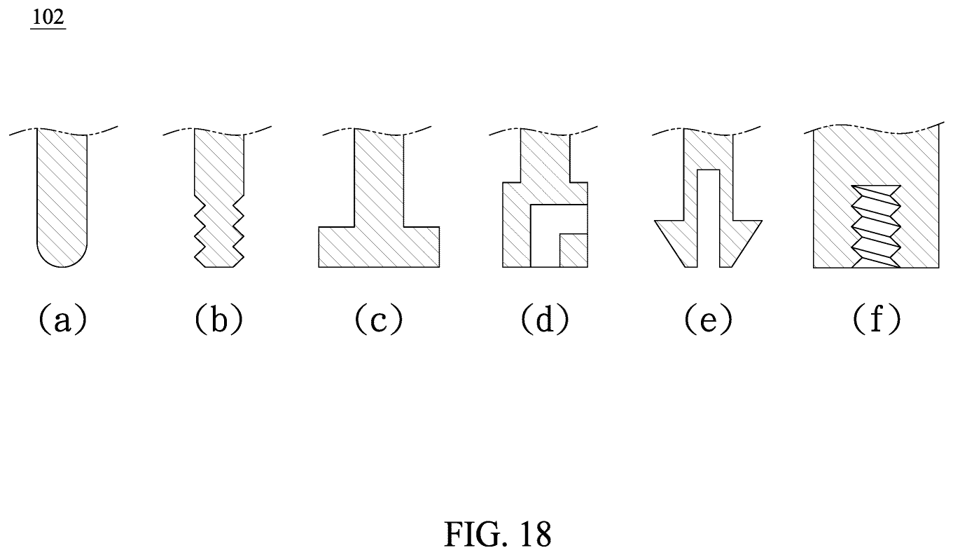

Referring to FIG. 18, as shown in the drawing, in addition to the embodiments above, in one embodiment of the present disclosure, a difference from the embodiments above is that, the engaging connection structure 102 is a column body (as part a in FIG. 18), a threaded body (as part b in FIG. 18), an outer engaging body (as part c in FIG. 18), an inner engaging body (as part d in FIG. 18), an elastic engaging body (as part e in FIG. 18) or an inner threaded body (as part f in FIG. 18), the heat generator 20 is a chip, an IC, a GPU, a CPU, a memory, a heat dissipater, a non-metal body, a metal body, a conductive body or a battery, the object 30 is a printed circuit board, a chip, a conductive body, silicon wafer, a heat dissipater, a non-metal body or a metal body, the first elastic element 103 is a spring, an elastic piece, an elastic column, or an elastic sheet, the heat dissipater 10 (or the heat generator 20) is a fin body, a block body or a stacked body, or the heat generator 20 and the heat dissipater 10 are placed in a server, a memory, a computer or a data center, or the heat dissipater 10 (or the heat generator 20) can be a system having liquid circulation heat transfer (or a system connected to liquid circulation heat transfer). Thus, the present disclosure is able to better meet actual application requirements.

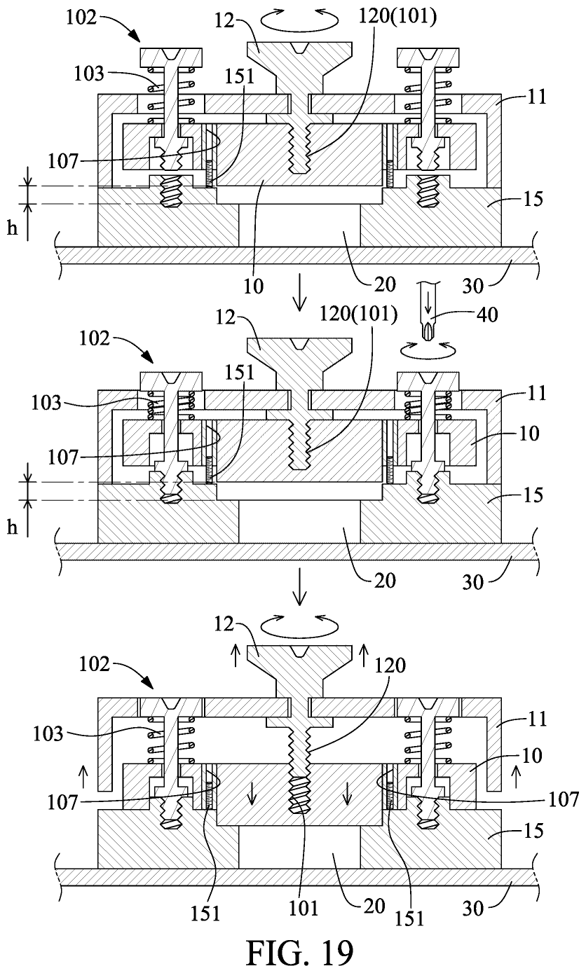

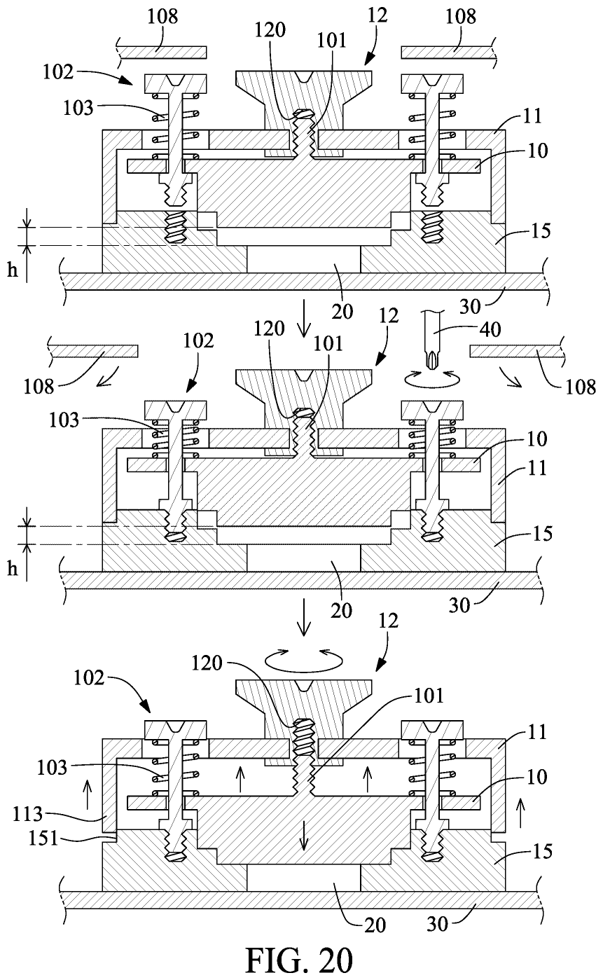

Referring to FIG. 19 and FIG. 20, as shown in the drawings, in addition to the embodiments above, in one embodiment of the present disclosure, a difference from the embodiments above is that, when the engaging connection structure 102 is not engagingly connected to the coupling portion 15 (or not engagingly connected to the object 30), the blocking structure 11 is placed to block the coupling portion 15 (or the object 30), the engaging connection structure 102 is engaged (or elastically engaged) with the coupling portion 15 (or the object 30) with coordination of the tool 40, and the twist connection portion 120 of the actuating body 12 is moved (twisted, rotated, or pulled) and connected to the twist-in portion 101 of the heat dissipater 10, so as to control, by moving the actuating body 12 or moving the blocking structure 11 or having the blocking structure 11 not block the coupling portion 15 or the object 30, the distance h between the heat dissipater 10 and the heat generator 20 (for example, located at a predetermined distance, reducing the distance or leaving no distance), for the heat dissipater 10 to be attached to (approach or come into contact with) the heat generator 20.

In addition to the embodiment above, in one embodiment of the present disclosure, a difference from the embodiments above is that, the twist connection portion 120 of the actuating body 12 can be a stud, and the twist-in portion 101 of the heat dissipater 10 can be a nut (as shown in FIG. 19), or the twist connection portion 120 of the actuating body 12 can be a nut and the twist-in portion 101 of the heat dissipater 10 can be a stud (as shown in FIG. 20). Thus, the present disclosure is able to better meet actual application requirements.

In addition to the embodiment above, in one embodiment of the present disclosure, a difference from the embodiments above is that, the coupling portion 15 and the heat dissipater 10 are provided with at least one limiting portion 151 and 107, which are for limiting or anti-rotation (as shown in FIG. 19) of the coupling portion 15 and the heat dissipater 10, or the object 30 and the heat dissipater 10 are provided with at least one limiting portion. Moreover, the coupling portion 15 and the blocking structure 11 can be provided with at least one limiting portion 151 and 113, which are for limiting or anti-rotation (as shown in FIG. 20) of the coupling portion 15 and the blocking structure 11, or the object 30 and the blocking structure 11 are provided with at least one limiting portion. Thus, the present disclosure is able to better meet actual application requirements.

In addition to the embodiment above, in one embodiment of the present disclosure, a difference from the embodiments above is that, a safety member 108 is provided at a position near or above the engaging connection structure 102. The safety member 108 is for limiting an operation of the engaging connection structure 102, or the safety member 108 is for limiting the tool 40 from operating the engaging connection structure 102. Moreover, once it is confirmed that the blocking structure 11 blocks the coupling portion 15 (or the object 30), the safety member 108 is moved away so as to operate the engaging connection structure 102 (as shown in FIG. 20). Thus, the present disclosure is able to better meet actual application requirements.

The present invention is described by way of the preferred embodiments above. A person skilled in the art should understand that, these embodiments are merely for illustrating the present invention and are not to be construed as limitations to the scope of the present invention. It should be noted that all equivalent changes, replacements and substitutions made to the embodiments are encompassed within the scope of the present invention. Therefore, the legal protection for the present invention should be defined by the appended claims.

What is claimed is:

1. A blocking device, comprising:
a blocking structure; and
an actuating body, disposed at the blocking structure, the actuating body for being disposed at a heat dissipater, so as to control a distance between the heat dissipater and a heat generator by the actuating body, or to control, by the actuating body and the blocking structure, the heat dissipater to come into contact or not to come into contact with the heat generator.

2. The blocking device according to claim 1, further comprising:
a body, the body disposed or movably disposed at the blocking structure, or the body and the heat dissipater being assembled, or the body and the heat dissipater being formed integrally.

3. The blocking device according to claim 1, wherein the actuating body is twisted into or screwed into a twist-in portion or screw-in portion of the heat dissipater, or so as to control the distance between the heat dissipater and the heat generator by the actuating body.

4. The blocking device according to claim 1, wherein the heat dissipater is provided with an engaging connection structure and at least one first elastic element, or the engaging connection structure for engagingly connected to an object or a coupling portion, or for pressing, or by elastic force of the first elastic element, the heat dissipater at the heat generator for heat dissipation, or for the heat dissipater to come into contact with or approach the heat generator for heat dissipation, or wherein the heat dissipater is provided with four engaging connection structures and four first elastic elements, and the engaging connection structure is for being engagingly connected to an object or a coupling portion, or for pressing, by elastic force of the first elastic element, the heat dissipater at the heat generator for heat dissipation, or for the heat dissipater to come into contact with or approach the heat generator for heat dissipation, or wherein the heat dissipater is provided with an engaging connection structure, or the engaging connection structure is for being engagingly connected to an object or a coupling portion, or for the heat dissipater to be pressed at the heat generator for heat dissipation, or for the heat dissipater to come into contact with or approach the heat generator for heat dissipation.

5. The blocking device according to claim 1, wherein the heat dissipater is provided with an engaging connection structure, or the blocking structure is provided with at least one open portion, and the open portion is for a tool to enter so as to operate the engaging connection structure or to move out the engaging connection structure from the open portion.

6. The blocking device according to claim 1, wherein the blocking structure or the heat dissipater is provided with at least one alignment portion, or the alignment portion is for alignment of the blocking structure or the heat dissipater.

7. The blocking device according to claim 1, wherein the actuating body or the heat dissipater is a threaded body, an engaging body, a spiral body, a pulling structure, an abutment structure, a screw-in body, a screw or a nut, or the actuating body or a twist-in portion of the heat dissipater is a threaded body, an engaging body, a spiral body, a pulling structure, an abutment structure, a screw-in body, a screw or a nut, or the actuating body and the heat dissipater are locked, twist connected, screwed, engaged, bolted, adhered, expansion connected, riveted, welded or formed integrally.

8. The blocking device according to claim 1, wherein the heat dissipater is provided with a passage, or the passage is for circulating a fluid, or the fluid is a liquid or a gas or for dissipating heat of the heat generator.

9. The blocking device according to claim 1, wherein the actuating body is provided with a blocking portion, or the blocking portion is for limiting a rotation height of the actuating body, or the actuating body is provided with a limiting portion, or the limiting portion is for limiting the blocking structure.

10. The blocking device according to claim 1, wherein the actuating body is located at a high abutment position or a low abutment position during an operation, or is for moving the blocking structure, or the actuating body is provided with an operating portion, or for a force to be applied to the operating portion to operate the actuating body, or the actuating body is provided with an operating portion, or the operating portion and the actuating body are for being bolted and assembled by a bolt, or for a force to be applied to the operating portion to operate the actuating body, or the actuating body is provided with an operating portion, or the operating portion has a guide surface, or the guide surface is for guiding the actuating body to move and enter an entry portion, for the actuating body to be located and move at a high abutment position or a low abutment position, or the actuating body is provided with an operating portion, or the operating portion is for laterally blocking the actuating body, or for the actuating body to be located and move at a high abutment position or a low abutment position.

11. The blocking device according to claim 1, further comprising:
a second elastic element, or wherein two ends of the second elastic element respectively abut against the actuating body and the heat dissipater, or two ends of the second elastic element respectively abut against the blocking structure and the heat dissipater.

12. The blocking device according to claim 1, wherein the actuating body abuts against an object by the blocking structure during an operation, or is for pulling the heat dissipater upward, or for a distance to be present between the heat dissipater and the heat generator.

13. The blocking device according to claim 1, wherein the blocking structure has a restricting portion, or the restricting portion is for restricting a position of the actuating body, or the restricting portion is for restricting a position of an operating portion of the actuating body, or the restricting portion is for restricting the actuating body or for controlling and limiting a distance between or positions of the heat dissipater and the heat generator.

14. The blocking device according to claim 1, wherein the actuating body presses the blocking structure downward or is for abutting the blocking structure at an object, or for the actuating body to be pressed downward to pull upward the heat dissipater, or for a distance to be present between the heat dissipater and the heat generator, or for increasing a distance between the heat dissipater and the heat generator.

15. The blocking device according to claim 1, wherein the actuating body is provided with an operating portion, or the operating portion is operated by a tool, or the operating portion is operated to assemble the actuating body with the heat dissipater or the blocking structure, or an anti-loosening object is provided between the actuating body and the heat dissipater.

16. The blocking device according to claim 1, wherein the actuating body is provided with a stop portion, or the stop portion limits and assembles the actuating body and the blocking structure, or is provided with an elastic element, or two ends of the elastic element respectively abut against the actuating body and the blocking structure, or wherein the stop portion is a sheet, a washer or a sleeve film, or the stop portion and the actuating body are formed integrally.

17. The blocking device according to claim 1, wherein the blocking device is assembled with a coupling portion, or the coupling portion is for being arranged at an object, or the coupling portion is an object arranged with the heat generator, or the coupling portion is the object, or the object is a printed circuit board, or the coupling portion is a metal body, or the coupling portion or the object is for surrounding the heat generator, a chip or a chip heat generator, or the coupling portion is an object defining a coupling height, or the coupling portion is a heat dissipater, or the coupling portion is an engaging body, an engaged body, an assembly portion or a conductive body.

18. The blocking device according to claim 1, wherein the heat dissipater is provided with an engaging connection structure, or the engaging connection structure is a threaded body, a column body, an outer engaging body, an inner engaging body, an elastic engaging body or an inner threaded body, or wherein the heat generator is a chip, an IC, a GPU, a CPU, a memory, a heat dissipater, a non-metal body, a metal body, a conductive body or a battery, or the heat generator is disposed at an object, the object is a printed circuit board, a chip, a conductive body, silicon wafer, a heat dissipater, a non-metal body or a metal body, or the heat dissipater is provided with an engaging connection structure, or wherein a first elastic element is included, or the first elastic element is a spring, an elastic piece, an elastic column, or an elastic sheet, or the heat dissipater is a fin body, a block body or a stacked body, or the heat generator or the heat dissipater is placed in a server, a memory, a computer or a data center, or the heat dissipater or the heat generator is a system having liquid circulation heat transfer or a system connected to liquid circulation heat transfer.

19. The blocking device according to claim 1, wherein the actuating body or the heat dissipater includes a threaded structure, a screw structure, a rotation structure, an inclined structure or an abutment structure; or a pitch of the threaded structure is configured to decide a number of turn or an angle of rotation of the threaded structure when the heat dissipater contacts with the heat generator; or a pitch of the screw structure is configured to decide a number of turn or an angle of rotation of the screw structure when the heat dissipater contacts with the heat generator; or a pitch of the rotation structure is configured to decide a number of turn or an angle of rotation of the rotation structure when the heat dissipater contacts with the heat generator; or the threaded structure, the screw structure, the rotation structure, the inclined structure or the abutment structure is an external thread structure, an internal thread structure, an up and down moving rotation structure or a leverage structure.

20. A blocking method of a blocking device comprising:
providing a blocking structure; and
providing an actuating body, disposed at the blocking structure, the actuating body for being disposed at a heat dissipater, or for controlling a distance between the heat dissipater and a heat generator by the actuating body, or for controlling, by the actuating body and the blocking structure, the heat dissipater to come into contact or not to come into contact with the heat generator.

21. The blocking method according to claim 20, wherein the actuating body or the heat dissipater includes a threaded structure, a screw structure, a rotation structure, an inclined structure or an abutment structure; or a pitch of the threaded structure is configured to decide a number of turn or an angle of rotation of the threaded structure when the heat dissipater contacts with the heat generator; or a pitch of the screw structure is configured to decide a number of turn or an angle of rotation of the screw structure when the heat dissipater contacts with the heat generator; or a pitch of the rotation structure is configured to decide a number of turn or an angle of rotation of the rotation structure when the heat dissipater contacts with the heat generator; or the threaded structure, the screw structure, the rotation structure, the inclined structure or the abutment structure is an external thread structure, an internal thread structure, an up and down moving rotation structure or a leverage structure.

22. A blocking method of a blocking device comprising:
providing a blocking structure; and
providing an actuating body, disposed at the blocking structure, the actuating body for being disposed at a heat dissipater, so as to control a distance between the heat dissipater and a heat generator by the actuating body, or to control, by the actuating body and the blocking structure, the heat dissipater to come into contact or not to come into contact with the heat generator, or wherein the heat dissipater is provided with an engaging connection structure and one first elastic element, or the engaging connection structure is for being engagingly connected to an object or a coupling portion, or is for pressing, by elastic force of the first elastic element, the heat dissipater at the heat generator for heat dissipation, or for the heat dissipater to come into contact with or approach the heat generator for heat dissipation, or wherein the heat dissipater is provided with four engaging connection structures and four first elastic elements, or the engaging connection structure is for being engagingly connected to an object or a coupling portion, and is for pressing, by elastic force of the first elastic element, the heat dissipater at the heat generator for heat dissipation, or for the heat dissipater to come into contact with or approach the heat generator for heat dissipation, or wherein the heat dissipater is provided with an engaging connection structure, or the engaging connection structure is for being engagingly connected to an object or a coupling portion, or for the heat dissipater to be pressed at the heat generator for heat dissipation, or for the heat dissipater to come into contact with or approach the heat generator for heat dissipation, or wherein the actuating body abuts against an object by the blocking structure during an operation, or for pulling the heat dissipater upward, for a distance to be present between the heat dissipater and the heat generator.
